(19) United States
(12) Patent Application Publication
(10) Pub. No.: US 2014/0302238 A1
(43) Pub. Date: Oct. 9, 2014

(54) Apparatus and Method for the Evaporation and Deposition of Materials

(71) Applicants: Robert Choquette, Sarasota, FL (US); Lawrence Egle, Sarasota, FL (US); Aaron Dickey, Sarasota, FL (US)

(72) Inventors: Robert Choquette, Sarasota, FL (US); Lawrence Egle, Sarasota, FL (US); Aaron Dickey, Sarasota, FL (US)

(73) Assignee: Mustang Vacuum Systems, Inc., Sarasota, FL (US)

(21) Appl. No.: 14/240,601

(22) PCT Filed: Aug. 24, 2012
(86) PCT No.: PCT/US2012/052281

§ 371 Date: Feb. 24, 2014

Related U.S. Application Data
(60) Provisional application No. 61/526,742, filed on Aug. 24, 2011.
(60) Provisional application No. 61/541,565, filed on Sep. 30, 2011.

(51) Int. Cl. C23C 14/54; C23C 14/14

(52) U.S. Cl. CPC C23C 14/542; C23C 14/14
USPC 427/248.1; 118/722

(57) ABSTRACT

An apparatus and method for the evaporation and deposition of materials onto a substrate. A material hopper assembly may receive source material. An agitator mechanism may be controlled for urging or advancing forward the source material. A grinding mechanism may be controlled for grinding source material. A heating pot vessel may be heated to evaporate the source material. The evaporated source material may be deposited on a proximate substrate. The rate of the deposition may be controlled in part by the agitator mechanism and/or the grinding mechanism. Temperature zones in a heating pot vessel may be independently controlled to evaporate the source material. A reactor chamber may be heated to allow the evaporated source materials to interact. A heated mesh may be charged to accelerate particles of the evaporated source materials onto the substrate.

This non-provisional patent application claims priority to, and incorporates herein by reference, both U.S. Provisional Patent Application No. 61/526,742 which was filed Aug. 24, 2011, and U.S. Provisional Patent Application No. 61/541,565 which was filed Sep. 30, 2011.

This application includes material which is subject to copyright protection. The copyright owner has no objection to the facsimile reproduction by anyone of the patent disclosure, as it appears in the Patent and Trademark Office files or records, but otherwise reserves all copyright rights whatsoever.

### FIELD OF THE INVENTION

The presently disclosed invention relates in general to the field of vacuum deposition systems, and in particular to an apparatus and method for the evaporation of materials, such as selenium, and the deposition of films of the evaporated materials, such as alloyed films, and further including valved crackers and effusion cells used in certain deposition systems.

### BACKGROUND OF THE INVENTION

Deposition of films of evaporated materials generally requires heating the materials until they evaporate and then exposing them to a deposition source. Apparatuses capable of evaporating such materials are known in the art. Such apparatuses, however, require the heating of large amounts (typically on the order of 1-100 liters) of source material at a time. Once the material has been used, the apparatus must be cooled, opened, cleaned, re-stocked, and re-heated before they can be used again. Due to the high temperatures at which the devices operate, the heating and cooling cycles can take substantial time, during which the apparatus is not in productive use.

In addition to such down-times required by prior art devices, because such devices operate at a high temperature and generally utilize valves that control the rate of depositing the evaporated material, specific protocols must be followed during the heating and cooling cycles to avoid seizing the valves or releasing potentially hazardous materials (particularly when selenium is being evaporated) due to improper valve sealing. More specifically, when such units are at high temperatures, the deposition valves and corresponding valve seats expand due to thermal conditions. When expanded, the deposition valve must be seated more deeply in the seat in order to achieve a seal than would be needed at lower temperatures. Accordingly, if the apparatus is cooled when this valve is fully seated, the valve will seize. However, if the deposition valve is not adequately seated after cooling, potentially dangerous materials may escape. Therefore, specific protocols are needed during heating and cooling to ensure the deposition valve remains sealed during and after cooling, but does not seize. Additionally, to avoid condensation in this valve mechanism, the valves typically need to be heated, thereby adding cost, complexity, and additional potential failure points to the apparatus.

Embodiments of the present invention address these shortcomings by providing a continuous source, on-demand evaporation apparatus that does not require the heating of large amounts of source material at once, can be resupplied without cooling the entire apparatus, and does not necessarily rely on thermally-sensitive heated valves to control the rate of deposition. The result is a superior and more flexible deposition apparatus with longer up-times between maintenance that is safer to operate.

Single crucible effusion cell deposition systems known in the art may allow for mixing materials and depositing alloyed films. Such systems, however, lack the ability to independently control the heating of each deposition material separately. In addition, such cells do not utilize secondary evaporators which allow comingling of evaporants, or meshes adapted to accelerate deposition or enhance alloyed structures after comingling. While plasma enhanced processing can be used with prior art effusion cells, such processing can damage thin alloyed films, thereby leading to a lower-quality end product. Certain embodiments of the presently disclosed invention addresses such limitations, inter alia, by providing for multi-clustered evaporative deposition apparatuses and related methods.

### SUMMARY OF THE INVENTION

The presently disclosed invention may be embodied in various forms, including but not limited to, the following apparatuses and methods for the evaporation and deposition of materials.

In an embodiment, an apparatus for the deposition of materials onto a substrate may comprise a material hopper assembly receiving source material and an agitator mechanism for the controlled urging or advancing forward of the source material. The apparatus may include a grinding mechanism for the controlled grinding of the source material. Further, the apparatus may comprise at least one heating pot vessel that is heated to evaporate the source material. The agitator mechanism may control the rate of supply of the source material into the heating pot vessel(s). A chamber may be heated to resist condensation of the evaporated source material received from the at least one heating pot vessel. The chamber may be an external chamber. In addition, a conduit may be heated to resist condensation of the evaporated source material received from the at least one heating pot vessel. The conduit may provide a pathway for the evaporated source material to reach the chamber. The chamber may be adapted for a substrate to pass proximate to transfer holes on the chamber. The evaporated source material may be deposited on the substrate as the evaporated source material escapes through the transfer holes on the chamber. The rate of the deposition of the evaporated source material on the substrate may be controlled in part by the agitator mechanism and/or the grinding mechanism.

In certain embodiments, the apparatus may further comprise temperature zones for heating pot vessel(s). The temperature zones may be independently controlled to reach temperatures that evaporate the source material. A reactor chamber may contain the evaporated source materials, and may be heated to allow the evaporated source materials to interact with one another. A heated mesh may be charged to accelerate particles of the evaporated source materials. The accelerated particles may be deposited on the substrate as the substrate passes proximate to the chamber.

In some embodiments, an apparatus for the deposition of materials onto a substrate may comprise at least one heating pot vessel having a plurality of temperature zones. Heating pot vessels may contain source material. The temperature zones may be independently controlled to reach temperatures that evaporate the source material. A reactor chamber may contain the evaporated source materials. The reactor chamber may be heated to allow the evaporated source materials to interact with one another to generate a deposition material. A heated mesh may be charged to accelerate particles of the deposition material to be deposited on a substrate.

In certain embodiments, such an apparatus may further comprise material hopper assemblies that may receive source material. Further, the apparatus may include a grinding mechanism for controlled grinding of the source material. The ground source materials may be provided to a heating pot vessel.

In some embodiments, the mesh may comprise tantalum. Heating pot vessels may comprise a pyrolitic boron nitride vessel, and may be insulated with temperature resistant alumina epoxy. The interaction of the evaporated source materials may be comingling, reacting, or mixing.

In an embodiment, the heating pot vessel may comprise a plurality of heating pot vessels. Each one of the heating pot vessels may have one temperature zone.

In an embodiment, the heating pot vessel may comprise one or more heating pot vessels. The temperature zones of the heating pot vessels may be insulated from one another within each of the heating pot vessels.

Similarly, an embodiment of a method for the deposition of materials onto a substrate may comprise feeding source material into a material hopper assembly and controlling an agitator mechanism for advancing forward the source material. In addition, the method may comprise controlling a grinding mechanism for grinding the source material. Further, the method may comprise heating a heating pot vessel(s) to evaporate the source material. The agitator mechanism may control the rate of supply of the source material into the heating pot vessel(s). A chamber may be heated to resist condensation of the evaporated source material received from the at least one heating pot vessel. The chamber may be an external chamber. In addition, a conduit may be heated to resist condensation of the evaporated source material received from the at least one heating pot vessel. The conduit may provide a pathway for the evaporated source material to reach the chamber. A substrate may be passed proximate to the chamber. The evaporated source material may be deposited on the substrate as the evaporated source material escapes through transfer holes on the chamber. The rate of the deposition of the evaporated source material on the substrate may be controlled in part by controlling the agitator mechanism and/or the grinding mechanism for grinding the source material.

In some embodiments, the method may further comprise the step of independently controlling temperature zones of heating pot vessel(s) to reach temperatures that evaporate the source material. A reactor chamber may contain the evaporated source materials, and may be heated. The heated reactor chamber may allow the evaporated source materials to interact with one another. The method may comprise heating a mesh. The mesh may be charged by the heating step. The charged mesh may accelerate particles of the evaporated source materials. The accelerated particles may deposit on the substrate as the substrate passes proximate to the chamber.

In certain embodiments, the method may comprise controlling the rate of the deposition of the evaporated source material on the substrate by varying the size of the ground source material formed by the grinding mechanism. Further, the method may comprise periodically renewing the source material while the heating pot vessel is being heated. The methods may also comprise pumping a gas into the grinding mechanism. The gas may force the source material through the grinding mechanism. The gas may be argon. The method may further comprise performing the recited steps under vacuum conditions.

In an embodiment, a method for the deposition of materials onto a substrate may comprise the step of independently controlling a plurality of temperature zones of heating pot vessel(s). The heating pot vessel(s) may contain source material. The temperature zones may reach temperatures that evaporate the source material. Further, the method may comprise heating a reactor chamber, which may contain the evaporated source materials. The heated reactor chamber may allow the evaporated source materials to interact with one another. A deposition material may be generated from the interaction of the evaporated source materials. In addition, the method may comprise heating a mesh. The mesh may be charged by the heating step. The charged mesh may accelerate particles of the deposition material. The accelerated particles may deposit on a substrate.

In some embodiments, the method may further comprise the steps of feeding source material into material hopper assemblies and controlling an agitator mechanism for advancing forward the source material. The method may also comprise controlling a grinding mechanism for grinding the source material. The source materials may be provided to the heating pot vessel(s). The agitator mechanism may control the rate of supply of the source material into the heating pot vessel(s). The rate of the deposition of the deposition material on the substrate may be controlled in part by controlling the agitator mechanism and/or the grinding mechanism for grinding the source material.

In certain embodiments of the apparatus and method, the mesh may comprise tantalum. Further, the heating pot vessel(s) may comprise a pyrolitic boron nitride vessel. The heating pot vessels may be insulated with temperature resistant alumina epoxy. The interaction of the evaporated source materials may be comingling, reacting or mixing.

In some embodiments of the apparatus and method, the heating pot vessel(s) may comprise a plurality of heating pot vessels. Each one of the heating pot vessels may have one temperature zone. In some embodiments, the heating pot vessel(s) may comprise one or more heating pot vessels having a plurality of temperature zones insulated from one another within each of the one or more heating pot vessels.

In certain embodiments of the apparatus and method, the heating pot vessel(s) may be wrapped by a heating wire having at least two independent temperature sections. The first section of the heating wire may be wrapped around a first temperature zone of the heating pot vessel. The second section may be wrapped around a second zone of the heating pot vessel. The heating wire may comprise a nickel-chrome heater wire. The step of heating the mesh may be powered by a power supply that is further used to heat the heating pot vessel and the reaction chamber.

In an embodiment of the apparatus and method, monitoring and controlling the temperature sections of the heating wire may be performed with a Type K thermocouple. As a result, the temperature zones of the heating pot vessel(s) may be controlled. The method may further comprise monitoring the deposition composition. The deposition composition may be monitored by an in-situ vapor flux monitor or an in-situ x-ray fluorescence.

In an embodiment of the apparatus and method, the heating pot vessel may be located outside an evacuated chamber. The evaporated source material may be allowed to enter the reaction chamber via a heating pot exit tube. The heating pot vessel may be located within an evacuated chamber, and the heating pot vessel may be directly connected to the reaction chamber.

In an embodiment of the apparatus and method, the heating pot vessel and the reaction chamber may have independent temperature control capabilities. Further, the method may comprise maintaining a relative vacuum in the heating pot vessel. Concentrations of each of the source material may be controlled by independently controlling the temperature zones of the heating pot vessel. The temperature zones may be independently controlled by independently varying the electrical power utilized to heat each of the temperature zones.

In some embodiments of the apparatus and method, the deposition of the deposition material on the substrate may be controlled in part by adjusting the size of the mesh, adjusting the electrical power utilized to heat the mesh, and adjusting the distance between the deposition material and the substrate. In certain embodiments of the apparatus and method, the source material may comprise selenium, copper, indium, gallium, aluminum, sulfur, or phosphorous.

### BRIEF DESCRIPTION OF THE DRAWINGS

The foregoing and other objects, features, and advantages of the invention will be apparent from the following more particular description of embodiments as illustrated in the accompanying drawings, in which reference characters refer to the same parts throughout the various views. The drawings are not necessarily to scale, emphasis instead being placed upon illustrating principles of the invention.

FIG. 1 shows a perspective view of an apparatus, in accordance with certain embodiments of the invention.

FIG. 2 illustrates a sectional view of the embodiment shown in FIG. 1.

FIG. 3 shows a perspective, sectional view of a material hopper assembly and outer vessel, in accordance with certain embodiments of the invention.

FIG. 4 shows a perspective, sectional view of a grinder assembly, in accordance with certain embodiments of the invention.

FIG. 5 shows a sectional, close-up view of the lower portion of a grinder assembly, in accordance with certain embodiments of the invention.

FIG. 6 shows a side view of a heating pot assembly, in accordance with certain embodiments of the invention.

FIG. 7 shows a perspective view of a heating pot assembly, in accordance with certain embodiments of the invention.

FIG. 8 shows an exploded, perspective view of a heating pot assembly, in accordance with certain embodiments of the invention.

FIG. 9 shows a perspective view of a heated transfer tube assembly, in accordance with certain embodiments of the invention.

FIG. 10 shows a perspective view of an external tube assembly, in accordance with certain embodiments of the invention.

FIG. 11 shows an exploded, perspective view of an external tube assembly, in accordance with certain embodiments of the invention.

FIG. 12 is a flowchart illustrating steps of a method for the evaporation and deposition of materials, in accordance with certain embodiments of the invention.

FIG. 13 is a perspective view of an apparatus utilizing multiple exterior vessels, in accordance with certain embodiments of the invention.

FIG. 14 is another perspective view of an apparatus utilizing multiple exterior vessels, in accordance with certain embodiments of the invention

FIG. 15 is a perspective view of an embodiment of the apparatus of the present invention utilizing multiple interior vessels.

FIG. 16 is a flowchart illustrating steps of a method for the evaporation and deposition of materials, in accordance with certain embodiments of the invention.

### DETAILED DESCRIPTION OF THE EMBODIMENTS

Reference will now be made in detail to the embodiments of the presently disclosed invention, examples of which are illustrated in the accompanying drawings.

Heating substances to high temperatures in environments relatively absent of oxygen can cause such substances to evaporate. The evaporated substances may then be deposited on deposition targets known as substrates. This may be accomplished with a heating pot vessel that evaporates the material and a pathway for the evaporated material to reach the deposition substrate. The pathway itself may also be heated to avoid material condensing prior to reaching the substrate.

There are various advantageous and benefits of the presently disclosed embodiments of the apparatus and method. In certain embodiments, one object is the ability to evaporate elemental selenium without the need for a deposition valve to control rate of depositing the evaporated material. Another object is the ability to control and stabilize selenium deposition rates by increasing or decreasing the speed of the grinding of the material being dropped onto the evaporator plate. Further, an object of an embodiment may be the ability to manipulate the type of selenium deposition, such as condensable solid or gas. An object may be the ability to increase or decrease the concentration density of the material being deposited, as well as increasing or decreasing the effective deposition, by varying the size of the evaporation plate. In addition, an object of an embodiment may include the ability to reload the elemental material in the hopper without the need for cooling down the source, breaking vacuum or interrupting production.

Accordingly, an embodiment of the present invention may relate to a continuous source, on-demand evaporation apparatus comprising a material hopper assembly, grinder assembly, heating pot assembly, heated transfer tube assembly, and external tube assembly. It will be understood that, while the embodiments described herein comprise a single material hopper assembly and grinder assembly leading into the heating pot assembly, other embodiments are also possible, and also within the scope of the present invention, in which multiple hopper and grinder assemblies, each feeding a different deposition material, are fed into a single heating pot assembly, thereby enabling the deposition of multi-source materials. Alternatively, the same result could also be achieved with multiple hopper and grinder assemblies each feeding their own heating pot assembly, which are, in turn each connected to a single external tube assembly.

As such, an object for certain embodiments of the present invention may relate to the ability to independently control the heating of each deposition material separately via a multi-source deposition device comprising a plurality of pyrolitic boron nitride vessels for evaporating source materials, a reactor chamber for comingling evaporated materials, and a charged tantalum mesh to promote uniform deposition of the evaporated materials. An embodiment may comprise a multi-cluster evaporative deposition apparatus with multiple, independently controlled evaporation sources, a secondary reactive chamber, and a tertiary charged mesh. The combination of multiple sources and tertiary evaporation allows for the creation of more uniform alloyed films without the need for plasma enhanced processing.

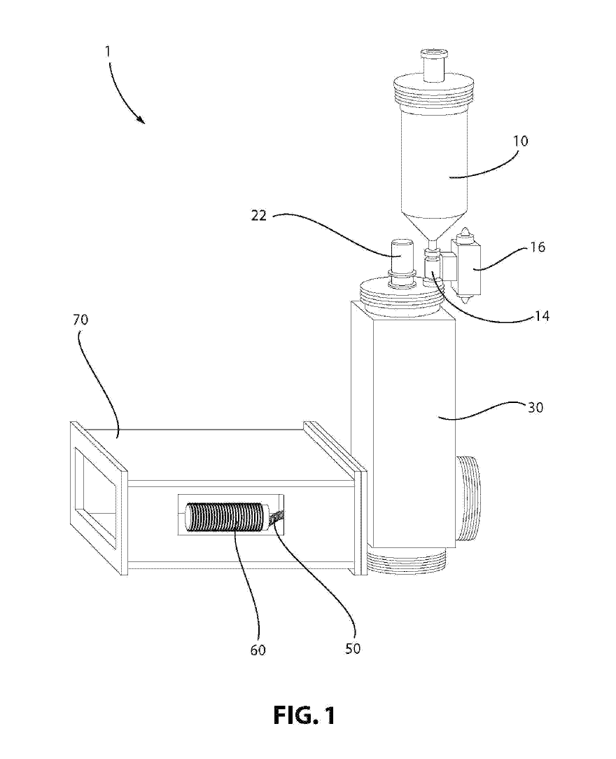

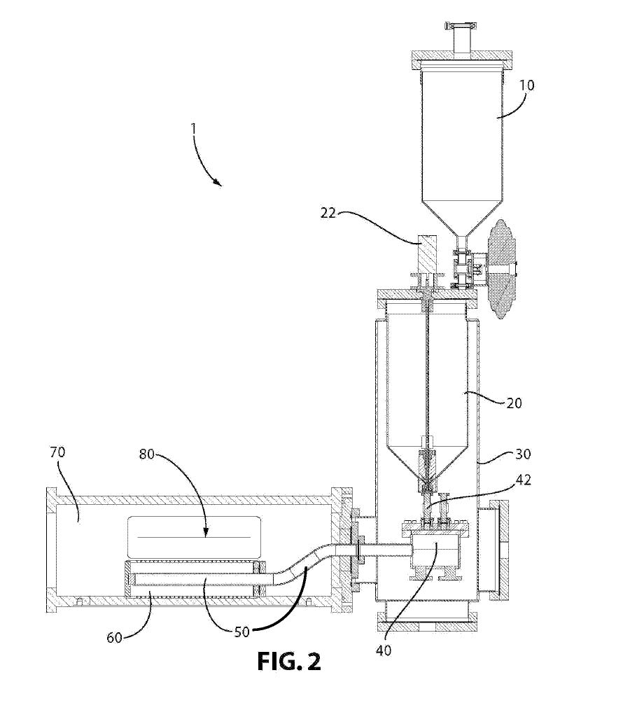

Referring now to FIGS. 1 and 2, an embodiment of an on-demand evaporation apparatus 1 of the present invention is illustrated. The on-demand evaporation apparatus 1 comprises a material hopper assembly 10 into which the source material may be inserted. The source material may be in pellet form. A loading valve 14 may be used to allow the source material to enter a grinder assembly 20. The grinder assembly 20 may be located within an outer vessel 30. The loading valve 14 may be a pneumatic or electrically actuated inline ball valve, such as those available from A & N Corporation as part number BVP-1002 NW. The loading valve 14 may be an actuated valve actuated by a loading valve actuator 16. Causing the loading valve actuator 16 to open the loading valve 14 will allow the source material to enter the grinder assembly 20 in order to be re-stocked as the source material is utilized in the deposition process. The grinder assembly 20 grinds the source material into small particles and feeds the small particles into a heating pot assembly 40, where the particles of source material may be evaporated. The rate of deposition material produced may be controlled by the rate of grinding, which may be controlled by a grinder motor 22. A heated transfer tube assembly 50 then allows the evaporate source material to travel to an external tube assembly 60 within a deposition chamber 70. As deposition substrate 80 passes through the deposition chamber 70, evaporated source material condenses on the deposition substrate 80, thereby coating the deposition substrate 80. The deposition substrate 80 may comprise a stainless steel web. The grinder assembly 20, the heating pot assembly 40, the heated transfer tube assembly 50, the external tube assembly 60, and the deposition chamber 70 may all be subject to a vacuum during the deposition process.

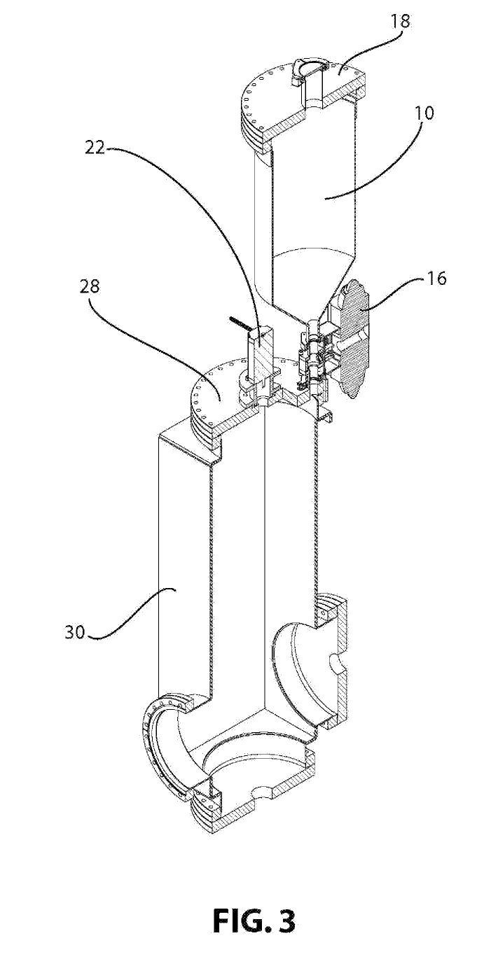

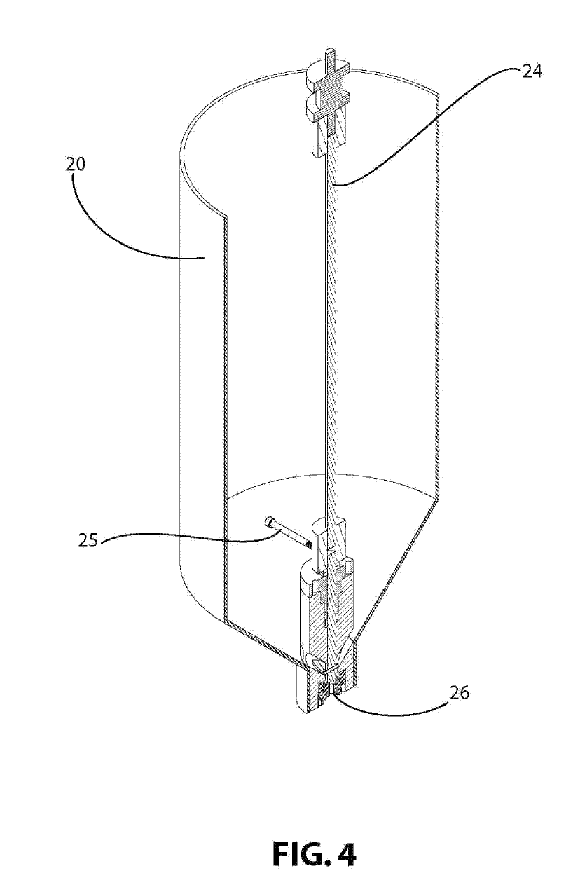

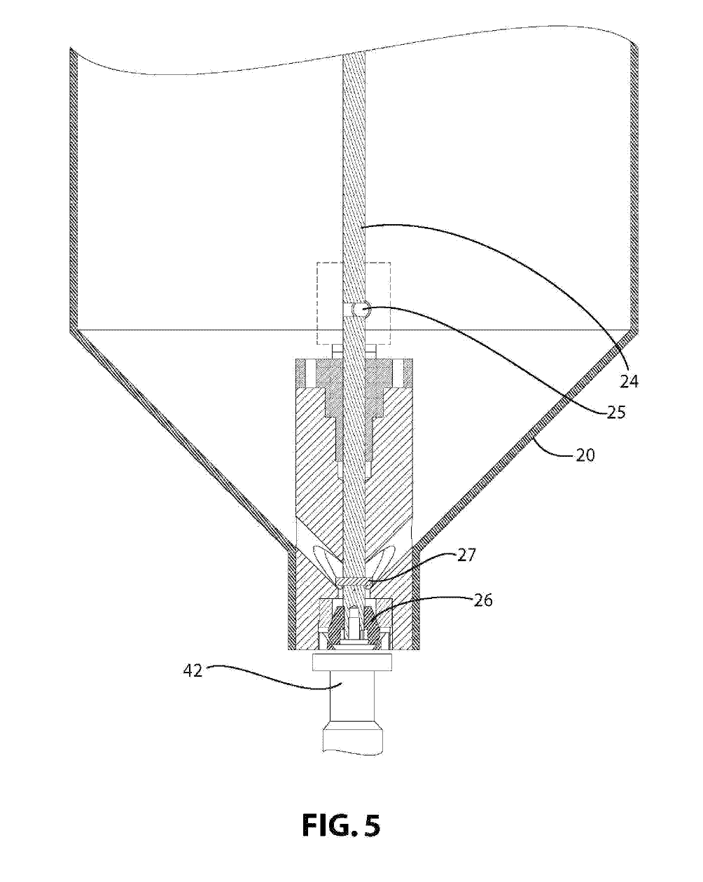

As shown in the embodiments illustrated in FIGS. 3-5, the material hopper assembly 10 may be a container with a funnel-shaped lower section. The material hopper assembly 10 may be made of stainless steel. The hopper sealing plate 18 allows new source material to be added to the material hopper assembly 10 during operation. The hopper sealing plate 18 may also fit tightly enough that the material hopper assembly 10 will remain under vacuum when the loading valve 14 is open. It will be understood that, after loading, air can be pre-evacuated from the material hopper assembly 10 prior to opening the loading valve 14 to assist in maintaining vacuum in the grinder assembly 20.

The grinder assembly 20 and the heating pot assembly 40 may be enclosed within the outer vessel 30, which may also be formed of stainless steel, in order to assist in maintaining a vacuum and to provide additional insulation from excess heat. The grinding motor 22 may be a variable speed electric motor with gear reduction, such as, without limitation, part number 23Y302S-LE8-1 available from Anaheim Automation. The grinding motor 22 may be mounted to grinder sealing plate 28 and connected to a grinder shaft 24. The grinder shaft 24 may be connected to grinding wheels 26, which may be adapted to grind the source materials into small particles in a manner similar to that used in traditional pepper grinders. The grinding wheels 26 may be of any sufficiently hard and heat resistant material such as, without limitation, aluminum oxide.

Grinding wheels 26 may be adjustable, typically by allowing the wheels 26 to be moved closer together or farther apart, in order to allow for adjustment of the size of the source material. When evaporating selenium according to one embodiment, a 300-micron distance between the grinding wheels 26 may be a suitable size for grinding the source material. By adjusting the speed of the grinding motor 22 for a given particle size, the rate of source material evaporation can be controlled without the use of a heated valve, such as is typical in the prior art. A grinder agitator 25 may be utilized to agitate the source material during grinding to assist in the flow of material into the grinding wheels 26. The grinder agitator 25 may be a bolt, post, or paddle attached to the grinder shaft 24. A second grinder agitator 27 may be utilized to further assist in achieving a consistent flow of material. The second grinder agitator 27 may be posts, bolts, or paddles positioned proximate to the grinding wheels 26.

The interior of the grinding assembly 20 may be maintained at a partial vacuum to help ensure that oxygen is not present during the evaporation process. Small concentrations of argon gas may optionally be introduced into the grinding assembly 20 to help maintain the flow of source material. In an embodiment, 1-10 cubic centimeters (cc) of argon per minute may be introduced into a 15-liter chamber in order to assist in maintaining the flow of ground material. The funnel shape in the lower end of grinder assembly 20 in certain embodiments may also be utilized to maintain the flow of ground material. The introduction of argon may be further utilized to maintain a slightly higher pressure in the grinding assembly 20 in order to prevent evaporant migration into the raw materials.

While a grinding assembly 20 may be necessary to grind source material supplied in pellet form, an agitator may be utilized to urge or advance forward source material from the material hopper assembly 10 into the heating pot assembly 40 when the source material is provided in a powder or small particle form which does not require grinding. The agitator may be utilized to agitate, push or shovel the source material to assist in the flow of material into the heating pot assembly 40. The agitator may be a bolt, post, or paddle. The agitator may be attached to the material hopper assembly 10 or the heating pot assembly 40. A second agitator may be utilized to further assist in achieving a consistent flow of material. The grinder agitators 25 and 27 described above may comprise such agitators for powdered source material. An agitator mechanism, comprising such an agitator, may control the rate of supply of the source material into the heating pot assembly 40. By controlling the rate of supply of the source material, the agitator mechanism may control in part the rate of the deposition of the evaporated source material on the substrate.

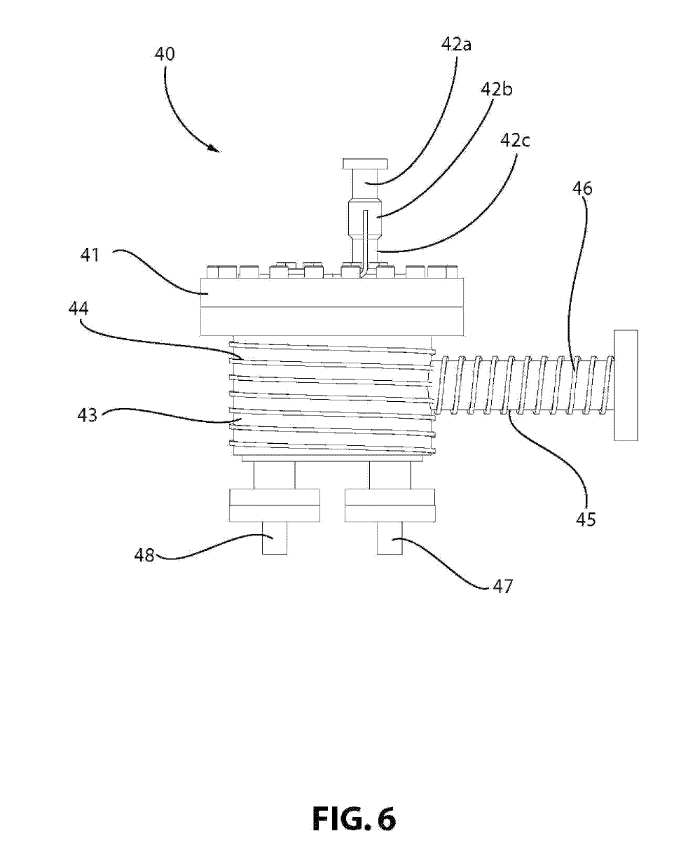

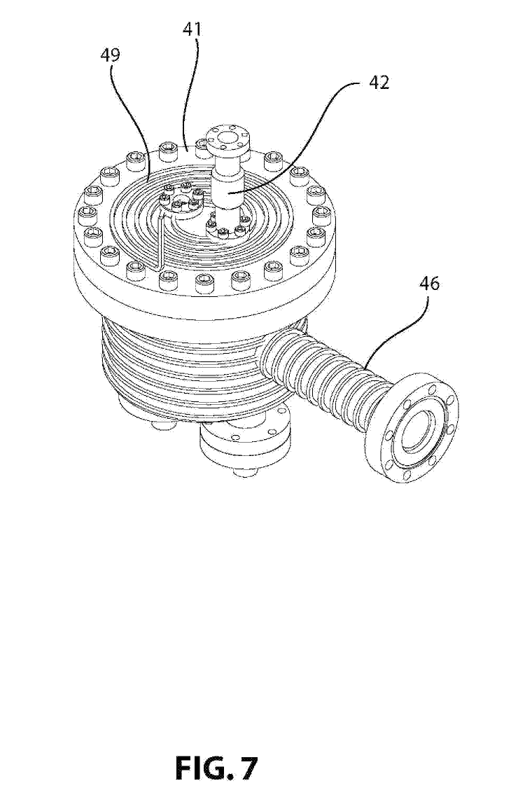

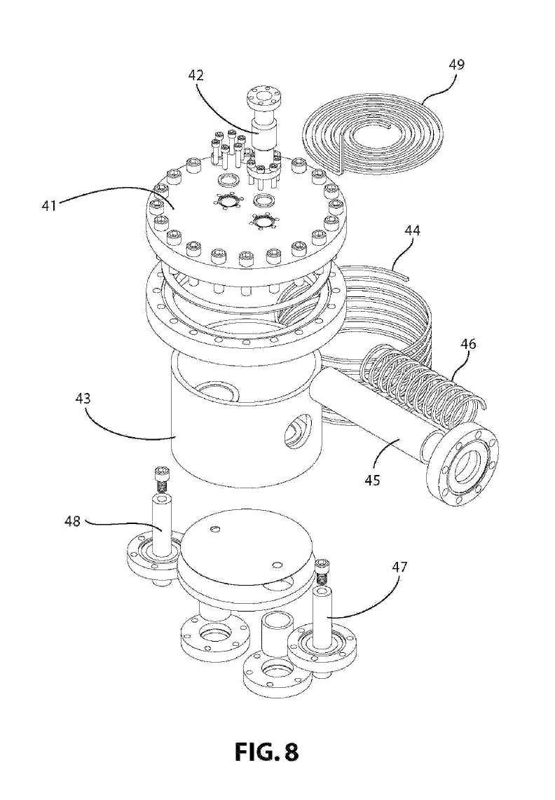

Referring now to the embodiments depicted in FIGS. 6-8, the heating pot assembly 40 may comprise a vacuum break 42. The vacuum break 42 may further comprise a section 42a operably attached to the output of the grinding wheels 26, a middle section 42b, and a section 42c attached to a heating pot sealing plate 41 to allow the ground material to enter the interior (the heating pot vessel 43) of the heating pot assembly 40. The heating pot assembly 40 may be maintained at vacuum and may be adapted to heat the ground source material to the point of evaporation. In an embodiment, the vacuum may be maintained at 2⁻⁷ Torr and the source material may be heated to temperatures of about 500-600 degrees Celsius.

In an embodiment, this can be accomplished with an internal vaporization plate (not illustrated) to which a low voltage, high amperage current may be applied via external heating coils. In an embodiment, the low voltage may be 5-10 Volts and the high amperage may be 300-800 Amperes. The heating coils may comprise a heating pot vessel coil 44 and a heating pot sealing plate coil 49. The heating pot vessel coil 44 may be an 1800 W/220V resistance heating coil wrapped around the heating pot vessel 43. The heating pot sealing plate coil 49 may be a 980 W/220V resistance heating coil wound about the top of the heating pot sealing plate 41.

In an embodiment, a heating pot exit tube 45 may provide an exit path for the evaporated material. The heating pot exit tube 45 may be heated with a heating pot exit tube coil 46. The heating pot exit tube coil 46 may be separate or integral to the heating pot vessel coil 44. A first heating pot standoff 47 and a second heating pot standoff 48 may support the heating pot assembly 40 and provide a path through which power may be connected to the internal vaporization plate (not illustrated). Maintaining high temperatures in the heating pot assembly 40 may be desirable as it tends to resist condensation of material within the assembly 40. In addition to providing a path for material, vacuum break 42 also provides a physical separation between the heating pot assembly 40 and the grinder assembly 20. As a result, the vacuum break 42 assists in preventing the temperature within the grinder assembly 20 from becoming high enough to melt or vaporize the source material prior to, or during, grinding.

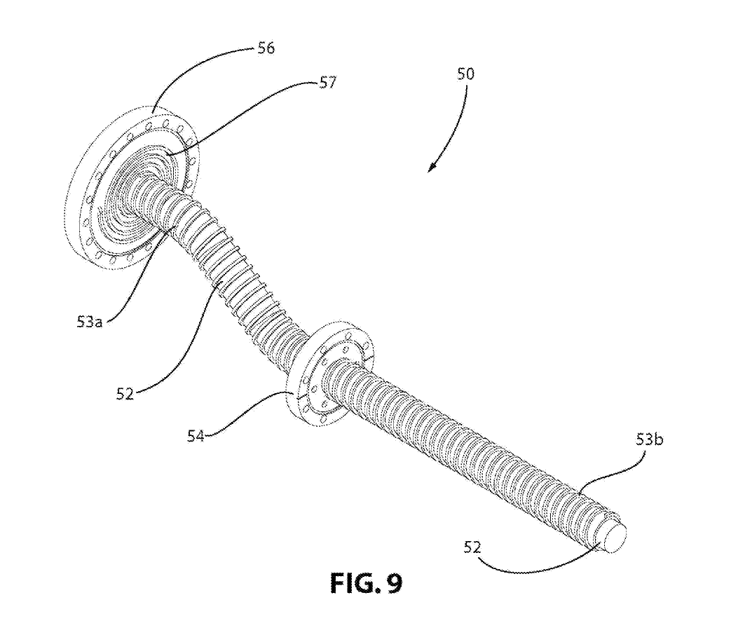

Referring back to FIG. 2, the heated transfer tube assembly 50 in an embodiment may be operably connected to the heating pot assembly 40, and may provide a pathway for the evaporated material. As shown in FIG. 9, the heated transfer tube assembly 50 may comprise a transfer tube 52 (which may be formed of stainless steel), a first transfer tube coil 53a and a second transfer tube coil 53b. These coils may be utilized to prevent condensation of the evaporated material before deposition occurs, and to enable creation of different temperature zones. Having multiple sections of heating coil allows for multiple temperature zones. The first transfer tube coil 53a may comprise a 5000 W/220V resistance heating coil, and the second transfer tube coil 53b may comprise a 7200 W/220V resistance heating coil. For longer transfer tubes 52 having additional temperature zones, additional heating coil sections may be utilized.

Transfer tube coils 53a and 53b may be adapted to heat the transfer tube 52 to a temperature higher than the heating pot assembly 40. In an embodiment, the transfer tube 52 may be heated up to about 900 degrees Celsius. Not only does such a high temperate resist condensation, it also urges the evaporated material along the pathway to the external tube assembly 60 (not shown). Allowing for multiple temperature zones assists in controlling the flow of material, as well as preventing early condensation.

A first transfer tube seal 56 allows the heated transfer tube assembly 50 to be operably attached to the heating pot assembly 40 (not shown). The first transfer tube seal 56 may be heated by a transfer tube seal coil 57, which may be an additional resistance heating coil. A second transfer tube seal 54 may be utilized to enable the heated transfer tube assembly 50 to be operably attached to an external tube assembly 60 (discussed further below). In this way, a portion of the heated transfer tube assembly 50 may extend within an external tube assembly 60 (not shown). The portion of the transfer tube 52 that extends within an external tube assembly 60 may have a plurality of holes (not illustrated) which allow the evaporated material to escape from inside the heated transfer tube assembly 50 into the external tube assembly 60. These holes may comprise any shape or size including, but not limited, to slits.

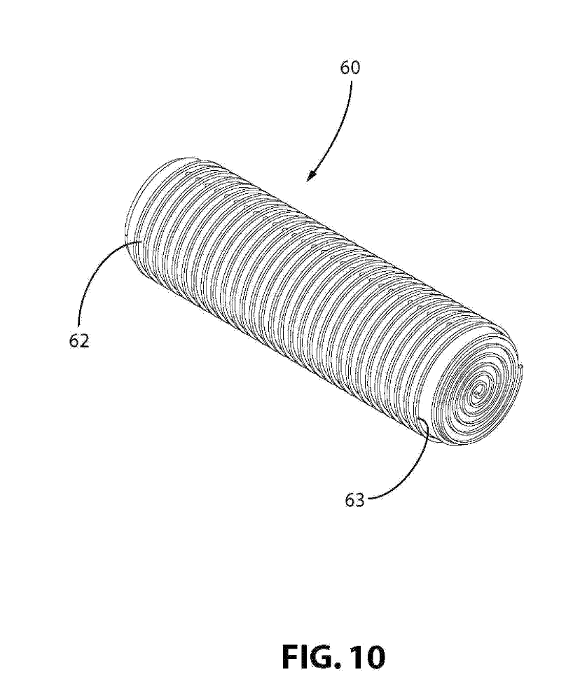

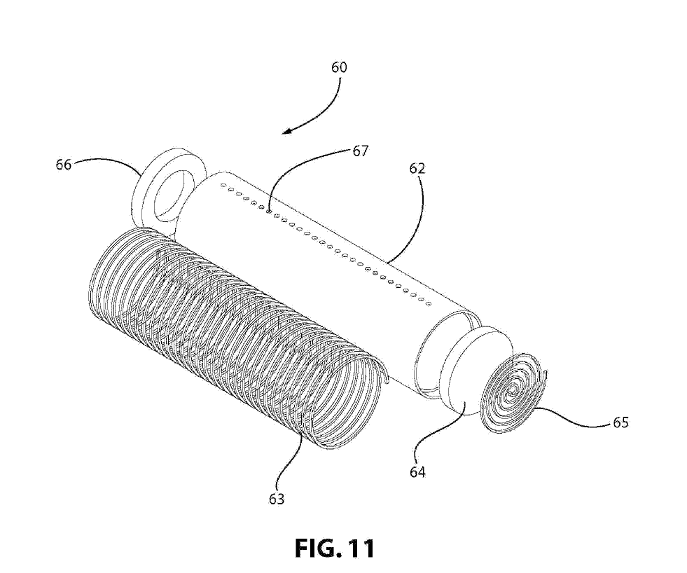

As depicted in the illustration of the embodiment shown in FIG. 2, the heated transfer tube assembly 50 may be extended within the external tube assembly 60, through which the evaporated material passes prior to deposition on substrate 80. Referring now to FIGS. 10-11, the external tube assembly 60 may comprise an external tube body 62 (which may be formed of stainless steel), an external tube cap 64, an external tube coil 63, an external tube connector 66, and an external tube cap coil 65. The external tube coil 63 and the external tube cap coil 65 may comprise heating coils adapted to maintain the external tube body 62 at a high temperature. In an embodiment, the external tube body 62 may be maintained at a high temperature up to about 900 degrees Celsius. The external tube body 62 may further comprise a plurality of transfer holes 67 through which the evaporated material passes so that the evaporated material may be deposited on the cooler deposition target 80, thereby creating the desired coating. The transfer holes 67 may comprise any shape or size including, but not limited, to slits.

The plurality of transfer holes 67 in the external tube body 62 may be oriented and positioned such that the transfer holes 67 are facing in the opposite direction of the plurality of holes in the portion of the transfer tube 52 that extends within an external tube assembly 60. In an embodiment, the transfer holes 67 may traverse a linear row along the longitude axis of the external tube body 62 on one side of the external tube body 62, while the holes in the transfer tube 52 traverse a linear row along the same longitude axis but facing the opposite side of the external tube body 62. As a result, the evaporated material exits the holes in the transfer tube 52 and then travels around the transfer tube 52 prior to reaching the transfer holes 67 in the external tube body 62. Such a configuration may promote the comingling of various evaporants within the external tube assembly 60. While the benefit provided by this configuration may be desirable for certain embodiments, the present invention may not be limited to any particular such configuration.

In an embodiment of a continuous source, on-demand evaporation apparatus, a material hopper assembly may be adapted to be sealed to the outside environment. A grinder assembly may be operably connected to the material hopper assembly by an actuated valve and adapted to be sealed to the outside environment. The grinder assembly may comprise an adjustable speed motor and a grinding means capable of adjusting the size of ground particles. A heating pot assembly may be adapted to be sealed to the outside environment and operably connected to said grinder assembly such that the ground particles flow from the grinding means to the heating pot assembly. An evaporation plate may evaporate the ground particles. A heated external tube assembly may be proximate to a deposition target and adapted to deposit evaporated material onto the target. A heated transfer tube assembly may operably connect the heating pot assembly and the external tube assembly.

In accordance with such an embodiment, source material may be loaded into the material hopper assembly while the valve is closed substantially without venting atmosphere into the grinder assembly. The source material may flow through the valve into the grinder assembly. The adjustable grinding means and adjustable speed motor may be adapted to deliver the ground particles into the heating pot at a predetermined rate. The evaporation plate may cause the ground particles to evaporate. The heated transfer tube assembly may allow the evaporated particles to transition to the external tube assembly substantially without condensing. The external tube assembly may deposit the evaporated particles onto the target.

In certain embodiments of this continuous source, on-demand evaporation apparatus, a gas source may be operably connected to the grinding assembly such that gas may flow into the grinding assembly during operation to aid in the flow of the source material into the grinding means. The gas may be argon, and the source material may comprise a plurality of selenium pellets. The heated transfer tube assembly may comprise at least two sections, each section capable of being heated to a different temperature. The material hopper assembly may be operably connected to a vacuum pump adapted to remove excess air from the material hopper assembly after loading. The variable speed motor and the valve may be automatically controlled by a control system.

In some of the embodiments, a plurality of material hopper assemblies may be included, each of which may be connected to a separate grinder assembly. Each of the separate grinder assemblies may be operably connected to a common heating pot assembly, whereby films comprising more than one material may be deposited onto the target. Each of the separate grinder assemblies and each of the separate grinder assemblies may be operably connected to a separate heating pot assembly. Each heating pot assembly may be operably connected to a separate heated transfer tube assembly. Each heated transfer tube assembly may be operably connected to the external tube assembly, whereby films comprising more than one material may be deposited onto the target and each of the materials may have a different evaporation temperature.

In an embodiment of a method of forming a coating on a target with an evaporated material, providing a supply of source material may be provided. The method may comprise grinding the source material prior to evaporation, evaporating the source material with a heating pot assembly, and transferring the evaporated source material through a heated transfer tube. Further, the method may comprise allowing the evaporated source material to deposit on the target. The rate of deposition may be controlled by varying the speed of the grinding. The rate of deposition may be controlled by varying the size of the particles formed during the grinding step. The source material may comprise selenium.

In addition, an embodiment of the method may further comprise the step of periodically renewing the supply of source material substantially without cooling the heating pot assembly. Further, the method may comprise the step of introducing a supply of a gas prior to the grinding step such that the gas may facilitate movement of the source material during the grinding step. The gas may be argon. The method may also comprise the step of performing the grinding step, the evaporating step, the transfer step, and the depositing step under vacuum conditions.

Utilizing embodiments of the on-demand apparatus 1 described above, or similar apparatuses, the manufacture of which will be apparent to those of skill in the art in light of the foregoing description, evaporated material may be deposited according to the following described method. An embodiment of a method for the presently disclosed invention may include the step of heating a heating pot vessel to a temperature sufficiently high enough to evaporate the source material. The heating pot vessel may be connected via a heated conduit to a chamber. The chamber may be an external chamber. The chamber may be proximate to a deposition target material and may have transfer holes through which the evaporated material can reach the deposition target. The method may also include the step of heating the conduit and chamber to a temperature at least high enough to resist condensation of the evaporated source therein.

In addition, the method may include the steps of providing a grinding chamber having a variable speed grinding mechanism operably connected to the heating pot, and evacuating the heating pot, the heated conduit, the heated chamber, and the grinding chamber to substantially eliminate oxygen. Further, the method may include the step of providing a source material hopper assembly operably connected to the grinding chamber and controlled by an actuated valve. Such method may also comprise providing source material into the material hopper assembly. A wide variety of materials can be deposited utilizing the apparatuses and methods of the present invention including, without limitation, selenium, copper, indium, gallium, aluminum, sulfur, and phosphorous. The method may include passing a deposition target proximate to the chamber. In this way, by controlling the speed of the grinding mechanism, the amount of material evaporated can be controlled without the use of high temperature valves and new source material can be added into the source material hopper without fully cooling and opening the apparatus.

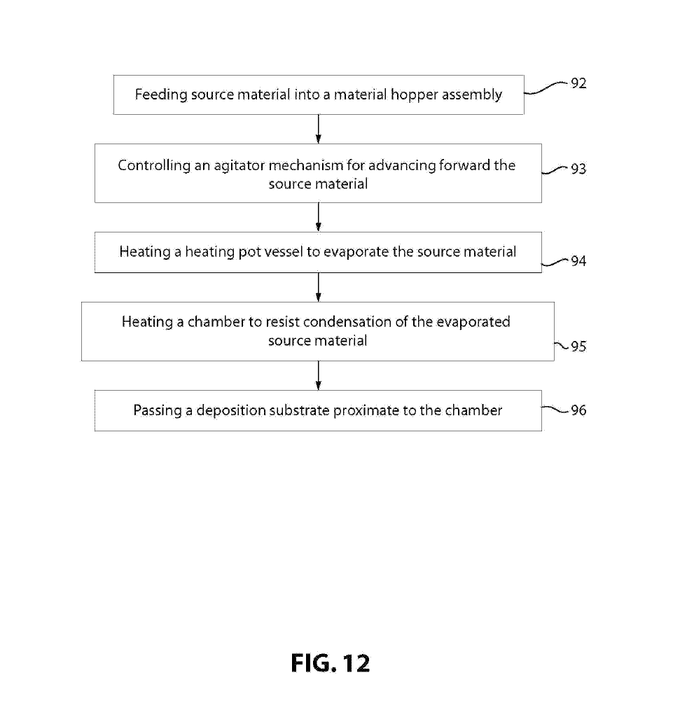

As illustrated in FIG. 12, a method for the evaporation and deposition of materials may comprise feeding 91 source material into a material hopper assembly, controlling 92 an agitator mechanism for advancing forward the source material, and heating 93 a heating pot vessel to evaporate the source material. Further, such a method may include heating 94 a chamber to resist condensation of the evaporated source material therein. In addition, the method may include passing 95 a deposition substrate proximate to the chamber to be targeted by the evaporated source material as it escapes through the transfer holes of the chamber. Certain embodiments of the method may also include independently controlling multiple temperature zones for heating pot vessel(s), separately heating a reactor chamber to allow the evaporated materials to react, and heating and charging of a tantalum mesh to accelerate and charge the materials to be uniformly deposited on the substrate.

In certain embodiments of such on-demand evaporation apparatuses and methods, an embodiment may comprise a material hopper, a grinder, a heated vessel with an evaporator plate, a transfer tube conductance passage, and a dual heated/dual temperature external tube nozzle. Each of these components may be independently controlled for temperature. Source material may be loaded in the hopper, fed down through the grinder and vaporized in the heated vessel. After the material exits the evaporator, it may be conducted through a secondary heated transfer tube re-evaporator and a tertiary evaporation external tube in order to create uniform deposition without spitting or droplets.

In embodiments where it is desirable to form coatings comprising multiple materials, multiple hopper 10 and grinder 20 assemblies may be used, all of which feed into a single heating pot assembly 40. Alternatively, multiple hoppers 10 and grinders 20 each could be connected to its own heating pot assembly 40. Each heating pot assembly 40 may then connected to heated transfer tube assemblies 50 that merge into the external tube assembly 60. In such embodiments, the composition of the materials can be controlled by varying the rate of grinding within each grinding assembly 20. The manufacture of multi-source embodiments will be apparent to those of skill in the art in light of this specification.

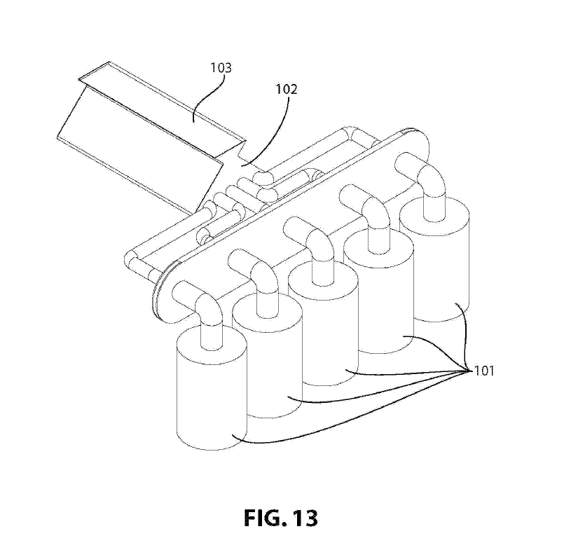

Accordingly, two or more evaporated substances can then be deposited on deposition targets. In certain embodiments, this may be accomplished with pyrolitic boron nitride vessels which have crucibles or hoppers for the source materials and multiple, independent temperature zones for heating and evaporating the source materials. Referring to FIGS. 13-15, embodiments of the present invention may utilize a plurality of pyrolitic boron nitride vessels 101 linked by a transit means to a reactor chamber 102 for comingling of the evaporated materials. A tantalum mesh 103 may promote uniform deposition of the alloy. Each of the vessels 101 may be independently heated. The vessels 101 may have two different temperature zones, one upper and one lower, and two different thermocouple feedback loops for controlling those temperature zones. In an embodiment, independent heating may be accomplished by wrapping each vessel 101 with two independent section of nickel-chrome heater wire (not illustrated) and insulating the sections with temperature-resistant alumina epoxy (not illustrated). The temperature zones may then be monitored and controlled with a Type K thermocouple (not illustrated), for closed loop feedback, thereby enabling the required temperature control. The vessels 101 may be mounted to metal or ceramic plates (not illustrated). A 1-5 kW DC power supply (not illustrated) may be utilized to heat the vessels 101 as well as the reactor chamber 102 and the tantalum screen (uniformer) 103, which are further discussed below.

While the vessels 101 may be arranged in a pentagon shape (not illustrated), the presently disclosed invention is not limited to any one layout, configuration or orientation. The vessels 101 may be orientated in such a way that the vapor plume from at least one vessel 101 has an indirect path through a transit means into the reactor chamber 102 (re-evaporator) in which, to some extent, deposition will occur on the interior walls. The reactor chamber 102 may be separately heated. Further, the reactor chamber 102 may allow for re-evaporation of any deposited materials and reactions among the separately evaporated materials.

The tantalum mesh 103 may move forward the reacted evaporative materials to exit the reactor chamber 102. The tantalum mesh 103 may be separately heated and electrically charged. The charging of the tantalum mesh 103 may accelerate and charge the deposition materials. The substrate (not illustrated) may pass over or thru the tantalum mesh 103 and receive the accelerated particles after they exit the comingling area of the reactor chamber 102. The charge and heating of the tantalum mesh 103 may be powered by the same DC power supply used to heat the vessels 101 and the reactor chamber 102. Temperature feedback may be achieved through direct contact feedback from an electrically isolated Type K thermocouple (not illustrated), as is understood in the art.

Deposition composition feedback may be closely monitored by either an in-situ vapor flux monitor (such as the “Guardian” manufactured by Inficon) (not illustrated) or an in-situ x-ray fluorescence (XRF) detector (such as those manufactured by Fischer Scientific) (not illustrated). The sizes and configurations of the vessels 101 may vary, and may be based on the area to be deposited.

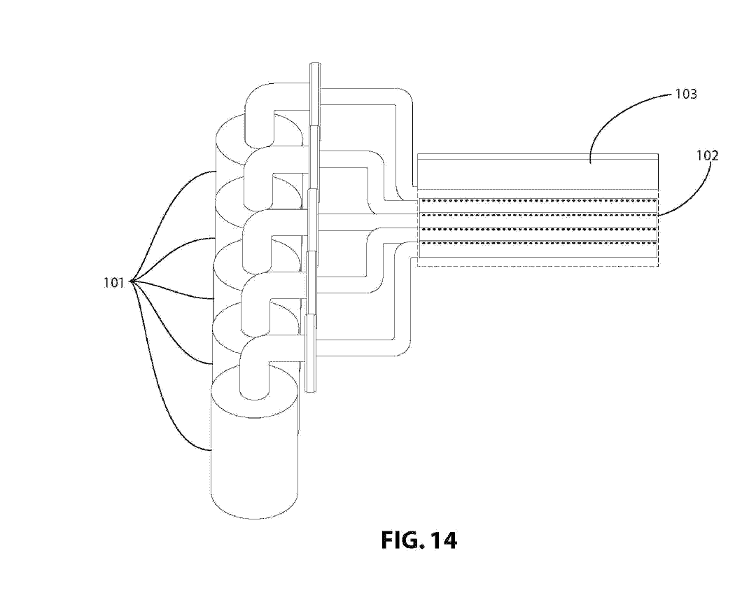

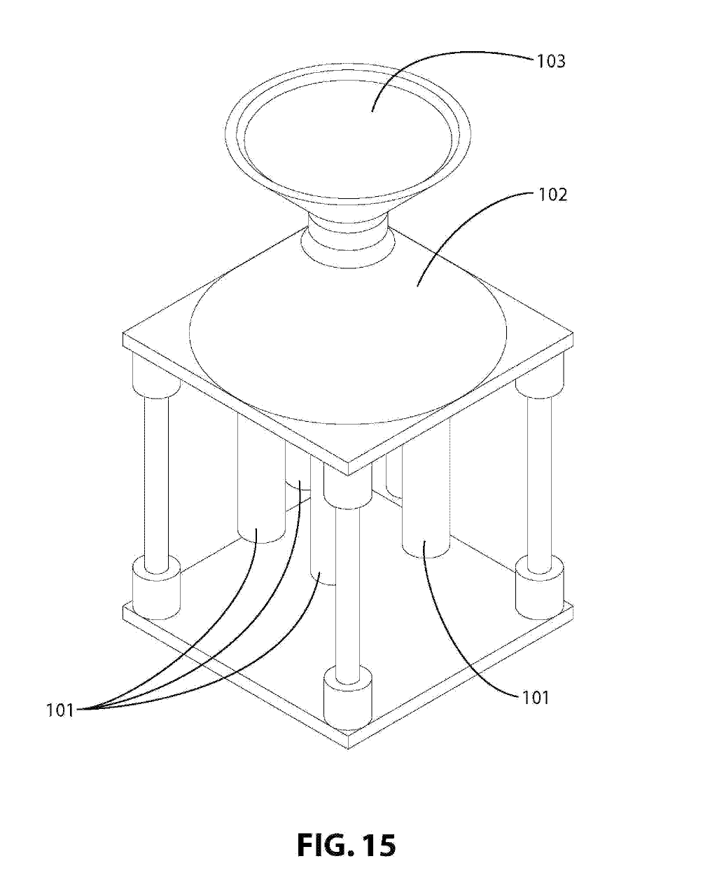

As illustrated in FIG. 15, an embodiment may include vessels 101 located within a reactor chamber 102; whereas in the embodiments in FIGS. 13-14, vessels 101 may be located outside the reactor chamber 102. As with the previously described embodiment, in the embodiment illustrated in FIG. 15, the vessels 101 may be pyrolitic boron nitride vessels. However, these vessels 101 may be directly linked to the reactor chamber 102. Each vessel 101 and the reactor chamber 102 may have separate heating and temperature control capabilities. Such capabilities may be driven by a single DC power source (not illustrated). The heating and temperature control mechanisms previously described may be applicable to both embodiments. At the exit of the reactor chamber 102, charged tantalum mesh 103 may accelerate and potentially charge the deposition material onto a substrate (not shown) over tantalum mesh 103. The tantalum mesh 103 may resist corrosion resulting from exposure to evaporated materials.

In an embodiment, a multi-source deposition apparatus may comprise a plurality of vessels, each of which defining a cavity capable of maintaining a vacuum. Such a vessel may further define an upper thermal zone and a lower thermal zone. Each of the thermal zones may be capable of maintaining separate thermal environments. A crucible may be contained within the lower thermal zone of each of the vessels. Each of the crucibles may have an opening, and the vessels may each have an aperture adapted such that material exiting the opening of a crucible may enter a transit means connected to an aperture of the corresponding vessel. The apparatus may also comprise a reactor chamber or zone that may be connected to the transit means. The reactor chamber may comprise a thermal zone and a charged and independently heated tantalum mesh. Each of the crucibles in each of the vessels may contain a separate material. The material may pass via an indirect path through the transit means to the reactor chamber, and through the mesh onto a deposition substrate.

In certain embodiments of such a multi-source deposition apparatus, the vessels may be pyrolitic boron nitride vessels comprising an upper thermocouple feedback loop adapted to control the temperature in the upper thermal zone and a lower thermocouple feedback loop adapted to control the temperature in the lower thermal zone. The vessels may be wound with an upper zone nickel-chrome heater wire wrap and an independent lower zone nickel-chrome heater wire wrap. Each vessel may be insulated with temperature resistant alumina epoxy. The upper zone nickel-chrome heater wire wrap and the lower zone nickel-chrome heater wire wrap may each be monitored with a Type K thermocouple, whereby a closed loop feedback circuit may be maintained. The vessels may be located outside of an evacuated chamber or inside an evacuated chamber.

An embodiment of a method of co-depositing multiple materials with such a multi-source deposition apparatus may comprise the steps of placing separate materials into at least two of the crucibles and maintaining a relative vacuum in the vessels containing the crucibles. Further, the method may comprise independently controlling the thermal environments of the vessels in order to cause the materials to enter the reactor chamber or zone. In addition, the method may comprise separately heating the reactor zone to allow the materials to react, and providing a charged screen at one end of the reactor zone through which the reacted materials may be deposited onto a substrate. Multiple source alloys that typically require a secondary reactive high temperature process may be separately evaporated, reacted and deposited onto a substrate. Co-deposited materials and single grain alloys may be deposited in one deposition multi-part step comprising materials evaporation, mixing in said reactor zone, and tertiary evaporation and acceleration through the mesh. The grain size, grain growth and grain structure may be controlled by varying the size of the screen mesh, the power applied to said mesh, and the source to substrate distance. The method may comprise the additional step of reclaiming and utilizing spent materials by re-evaporating them together in the reactor zone before condensing on the substrate.

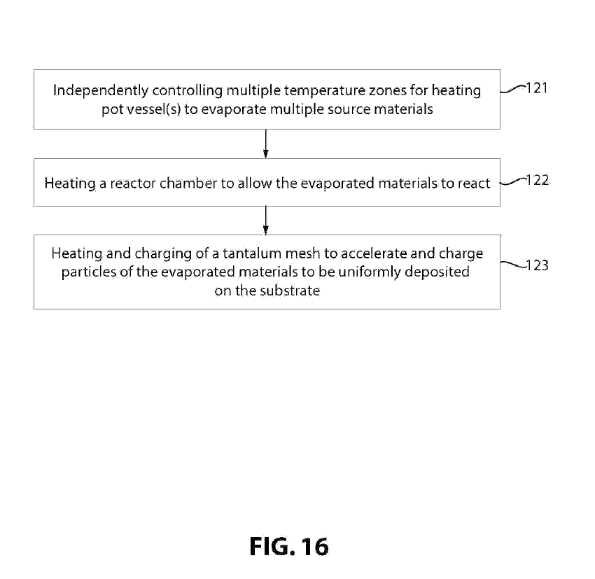

As illustrated in FIG. 16, a method for the evaporation and deposition of materials may comprise independently controlling 121 multiple temperature zones for heating pot vessel(s) to evaporate multiple source materials. Such source material may, or may not, be ground by a grinding mechanism. Further, such a method may include heating 122 a reactor chamber to allow the evaporated materials to react. Heating of the reactor chamber may be performed separately from heating of the heating pot vessel(s). In addition, the method may include the heating and charging 123 of a tantalum mesh to accelerate and charge particles of the evaporated materials to be uniformly deposited on the substrate. Certain embodiments of the method may also include feeding the source materials into material hopper assemblies, and controlling the speed of grinding mechanisms for grinding the source materials.

Although some of the drawings illustrate a number of operations in a particular order, operations which are not order-dependent may be reordered and other operations may be combined or broken out. While some reordering or other groupings are specifically mentioned, others will be apparent to those of ordinary skill in the art and so do not present an exhaustive list of alternatives. The term “adapted” shall mean sized, shaped, configured, dimensioned, oriented and arranged as appropriate.

While the invention has been particularly shown and described with reference to an embodiment thereof, it will be understood by those skilled in the art that various changes in form and details may be made therein without departing from the spirit and scope of the invention.

What is claimed is:

1. An apparatus for the deposition of materials onto a substrate, comprising:
a material hopper assembly receiving at least one source material;
an agitator mechanism for advancing forward the at least one source material;
at least one heating pot vessel heated to evaporate the source material, the agitator mechanism controlling the rate of supply of the at least one source material into the at least one heating pot vessel; and,
a chamber heated to resist condensation of the evaporated source material received from the at least one heating pot vessel; the chamber adapted for a substrate to pass proximate to transfer holes on the chamber, the evaporated source material depositing on the substrate as the evaporated source material escapes through the transfer holes on the chamber, the rate of the deposition of the evaporated source material on the substrate controlled in part by the agitator mechanism.

2. The apparatus of claim 1, further comprising:
a grinding mechanism for controlled grinding of the at least one source material, the rate of the deposition of the evaporated source material on the substrate controlled in part by the grinding mechanism for the controlled grinding of the at least one source material;

3. The apparatus of claim 1, further comprising:
a heated mesh charged to accelerate particles of the evaporated source materials, the accelerated particles depositing on the substrate as the substrate passes proximate to the chamber.

4. The apparatus of claim 1, the chamber comprising an external chamber.

5. The apparatus of claim 1, further comprising:
a conduit connecting the at least one heating pot vessel and the chamber, the conduit heated to resist condensation of the evaporated source material received from the at least one heating pot vessel.

6. The apparatus of claim 1, further comprising:
a plurality of temperature zones in the at least one heating pot vessel, the plurality of temperature zones independently controlled to reach temperatures that evaporate the at least one source material;
a reactor chamber containing the evaporated source materials, the reactor chamber heated to allow the evaporated source materials to interact with one another; and,
a heated mesh charged to accelerate particles of the evaporated source materials, the accelerated particles depositing on the substrate as the substrate passes proximate to the chamber.

7. An apparatus for the deposition of materials onto a substrate, comprising:
at least one heating pot vessel having a plurality of temperature zones, the at least one heating pot vessel containing at least one source material, the plurality of temperature zones independently controlled to reach temperatures that evaporate the at least one source material;
a reactor chamber containing the evaporated source materials, the reactor chamber heated to allow the evaporated source materials to interact with one another to generate a deposition material; and,
a heated mesh charged to accelerate particles of the deposition material to be deposited on a substrate.

8. The apparatus of claim 7, further comprising:
material hopper assemblies receiving source material; and,
an agitator mechanism for advancing forward the source material, the agitator mechanism controlling the rate of supply of the source material into the at least one heating pot vessel, the rate of the deposition of the deposition material on the substrate controlled in part by the agitator mechanism.

9. The apparatus of claim 7, further comprising:
a grinding mechanism for controlled grinding of the source material, wherein the ground source materials are provided to the at least one heating pot vessel, the rate of the deposition of the deposition material on the substrate controlled in part by the grinding mechanism for the controlled grinding of the at least one source material.

10. The apparatus of claim 7, the mesh comprising tantalum, the at least one heating pot vessel comprising a pyrolitic boron nitride vessel, and the at least one heating pot vessel insulated with temperature resistant alumina epoxy.

11. (canceled)

12. The apparatus of claim 7, the at least one heating pot vessel comprising a plurality of heating pot vessels, each one of the plurality of heating pot vessels having one temperature zone of the plurality of temperature zones.

13. The apparatus of claim 7, the at least one heating pot vessel comprising one or more heating pot vessels, the plurality of temperature zones of the one or more heating pot vessels being insulated from one another within each of the one or more heating pot vessels.

14. A method for the deposition of materials onto a substrate, comprising the steps of:
feeding at least one source material into a material hopper assembly;
controlling an agitator mechanism for advancing forward the at least one source material;
heating at least one heating pot vessel to evaporate the at least one source material, wherein the agitator mechanism controls the rate of supply of the at least one source material into the at least one heating pot vessel;
heating a chamber to resist condensation of the evaporated source material received from the at least one heating pot vessel; and,
passing a substrate proximate to the chamber, wherein the evaporated source material deposit on the substrate as the evaporated source material escapes through transfer holes on the chamber, wherein the rate of the deposition of the evaporated source material on the substrate is controlled in part by the step of controlling the agitator mechanism.

15. The method of claim 14, further comprising:
controlling a grinding mechanism for grinding the at least one source material, wherein the rate of the deposition of the evaporated source material on the substrate is controlled in part by the step of controlling the grinding mechanism for grinding the at least one source material.

16. The method of claim 14, further comprising:
heating a conduit to resist condensation of the evaporated source material received from the at least one heating pot vessel, wherein the conduit connects the at least one heating pot vessel and the chamber.

17. The method of claim 14, further comprising the steps of:
independently controlling a plurality of temperature zones of the at least one heating pot vessel, wherein the temperature zones reach temperatures that evaporate the at least one source material;
heating a reactor chamber, wherein the reactor chamber contains the evaporated source materials, wherein the heated reactor chamber allows the evaporated source materials to interact with one another; and,
heating a mesh, wherein the mesh is charged by the heating, wherein the charged mesh accelerates particles of the evaporated source materials, wherein the accelerated particles deposit on the substrate as the substrate passes proximate to the chamber.

18. The method of claim 14, further comprising the step of:
controlling the rate of the deposition of the evaporated source material on the substrate by varying the size of the ground source material formed by the grinding mechanism.

19. The method of claim 14, further comprising the step of:
periodically renewing the source material while the at least one heating pot vessel is being heated.

20. The method of claim 14, further comprising the step of:
pumping a gas into the grinding mechanism, wherein the gas forces the at least one source material through the grinding mechanism, wherein the gas is argon.

21. The method of claim 14, further comprising the step of:
performing the recited steps of the method under vacuum conditions.

22-42. (canceled)

43. The apparatus of claim 1, the at least one source material selected from a group consisting of selenium, copper, indium, gallium, aluminum, sulfur, and phosphorous.
